(19) United States
(12) Patent Application Publication
(10) Pub. No.: US 2001/0038126 A1
(43) Pub. Date: Nov. 8, 2001

(54) STRUCTURE FOR ESD PROTECTION WITH SINGLE CRYSTAL SILICON SIDED JUNCTION DIODE

(76) Inventors: FU-TAI LIOU, HSINCHU (TW); WEN-KUAN YEH, HSINCHU HSIEN (TW)

Correspondence Address: DANIEL R MCCLURE, THOMAS KAYDEN HORSTEMEYER, & RISLEY LLP SUITE 1500, 100 GALLERIA PARKWAY NW, ATLANTA, GA, 30339

(21) Appl. No.: 09/467,675

(22) Filed: Dec. 21, 1999

(51) Int. Cl. H01L 23/62

(52) U.S. Cl. 257/355

(57) ABSTRACT

An ESD protection structure having sided single crystal Si junction diode for protecting an internal circuit. The ESD protection structure is electrically coupled between an input pad and a node, and the internal circuit is electrically coupled to the node. The ESD protection structure includes at least a single crystal Si resistor, which is formed over an insulating material layer and electrically coupled between the input pad and the node. The ESD protection structure further includes at least a single crystal Si-sided junction diode, which is formed over the insulating material layer and electrically coupled between one terminal of corresponding power supply and the node.

### BACKGROUND OF THE INVENTION

1. Field of Invention

The present invention relates to electrostatic discharge (ESD) protection for an integrated circuit. More particularly, the present invention relates to an ESD protection structure having a single crystal Si-sided junction diode.

2. Description of Related Art

Electrostatic discharge is the major factor causing integrated circuit damage whether after completion of a wafer or during fabrication of a device such as a DRAM or SRAM. For example, when people walk on a carpet, hundreds and even thousands of volts in electrostatic charges can be detected in circumstances with high relative humidity (RH). When relative humidity is lower, over ten thousand volts of electrostatic charge are produced. Thus, if such carrier with electrostatic charges touches the wafer, the electrostatic charges on the carrier are discharged and result in failure of the wafer. Therefore, in order to prevent the wafer from being damaged by electrostatic discharge, various types of hardware and software have been developed. The conventional method of preventing electrostatic discharge is to design an ESD protection circuit between the internal circuit and each pad to protect an internal circuit.

FIG. 1 is a schematic diagram of a conventional ESD protection circuit. The ESD protection circuit 100 includes a polysilicon resistor 102, a protection circuit 104, and a P-type and N-type field effect transistor (FET). One end of the polysilicon resistor 102 is connected to an input pad 101 and the other end of the polysilicon resistor 102 is connected to a node 110 of the protection diode 104. The ESD protection circuit 100 is used to protect an internal circuit 111 from electrostatic charges.

Conventional ESD protection 100 is fabricated in bulk silicon (i.e. substrate). The polysilicon resistor 102 is formed over a substrate. The polysilicon resistor 102 is isolated from the substrate by an insulating material and electrically coupled to the protection diode 104 of FIG. 2. The protection diode 104 is fabricated in the bulk silicon, that is, the semiconductor substrate 200. The substrate 200 has the isolation structure 202 formed therein, which isolation structure 202 is used to define the active areas where a MOS, for example, can be formed. Such a MOS includes a gate 204 and source/drain region 206a, 206b. The protection diode 104 employs a P/N junction between the substrate 200 and the source/drain region 206a, 206b to allow current to transmit between the input pad 101 and V_{DD}, V_{SS}. Therefore, the electrostatic charges can be discharged, and the ESD protection 100 achieves the function of protecting the internal circuit 111.

Referring to FIGS. 1 and 2, when electrostatic current flows into the input pad 101, the P/N junction of the protection diode 104 fabricated in the bulk silicon 200 is turned on and enables the MOS transistor to turn “ON”, such that the electrostatic current can be discharged through the path between the diode 104 and V_{DD} or V_{SS}. Ideally, the electrostatic current should flow from one source/drain region 206a to the other source/drain region 206b through path I, as shown in FIG. 2. However, since the protection diode 104 is fabricated on the substrate 200, the electrostatic current may flow from the source/drain region 206a into the source/drain region 206b through path II. Accordingly, an unnecessary parasitic P/N junction may be produced between the source/drain region 206b, wells and contact regions (not shown), which results in an undesired effect. Alternatively, the current may flow through a vertical junction, such as path III, which leads to current leakage. The abnormal electrostatic current through path II or III causes failure of the ESD 100. As a result, the electrostatic current directly flows into the FET 107, 108 to damage the internal circuit 111, and the ESD 110 cannot protect the internal circuit 111 any more.

### SUMMARY OF THE INVENTION

The invention provides an electrostatic discharge protection structure having a single Si-sided junction diode, which ESD protection structure can protect the internal circuit from being damaged by electrostatic charges.

As embodied and broadly described herein, the invention provides an electrostatic discharge protection structure having a single crystal Si-sided junction diode, thereby protecting an internal circuit of the integrated circuit. The ESD protection structure is electrically coupled between an input pad and a node, and the internal circuit is electrically coupled to the node. The ESD protection structure includes at least a single crystal Si resistor, which is formed over an insulating material layer and electrically coupled between the input pad and the node. The ESD protection structure further includes at least a single crystal Si-sided junction diode, which is formed over the insulating material layer and electrically coupled between one terminal of corresponding power supply and the node. The single crystal Si resistor is made from a single silicon layer formed on the insulating material layer, and the single crystal Si-sided junction diode includes a lateral P/N junction formed on the insulating material layer.

The invention further provides a semiconductor structure of ESD protection, which is electrically coupled between an input pad and an integrated circuit. The semiconductor structure includes an insulating material layer formed on a semiconductor substrate. At least a single crystal Si resistor is located over the insulating material layer. At least a single crystal Si-sided junction diode is located over the insulating material layer. A first conductive layer located over the insulating material layer connects one end of the single crystal Si resistor and the input pad. A second conductive layer located over the insulating material layer connects another end of the single crystal Si resistor and the integrated circuit. A third conductive layer, located over the insulating material layer, connects the single crystal Si-sided junction diode and the integrated circuit. The single crystal Si resistor can be replaced by a plurality of single crystal resistors, and the single crystal Si-sided junction diode includes a lateral P/N junction.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is schematic electrostatic discharge protection circuit;

FIG. 2 is schematic, cross-sectional view of a portion of a protection diode;

FIG. 3 is schematic, cross-sectional view illustrating a semiconductor structure of ESD protection having single crystal Si-sided junction diode according to one preferred embodiment of this invention; and

FIG. 4 is schematic, cross sectional view illustrating a portion of the single crystal Si-sided junction diode according to one preferred embodiment of this invention.

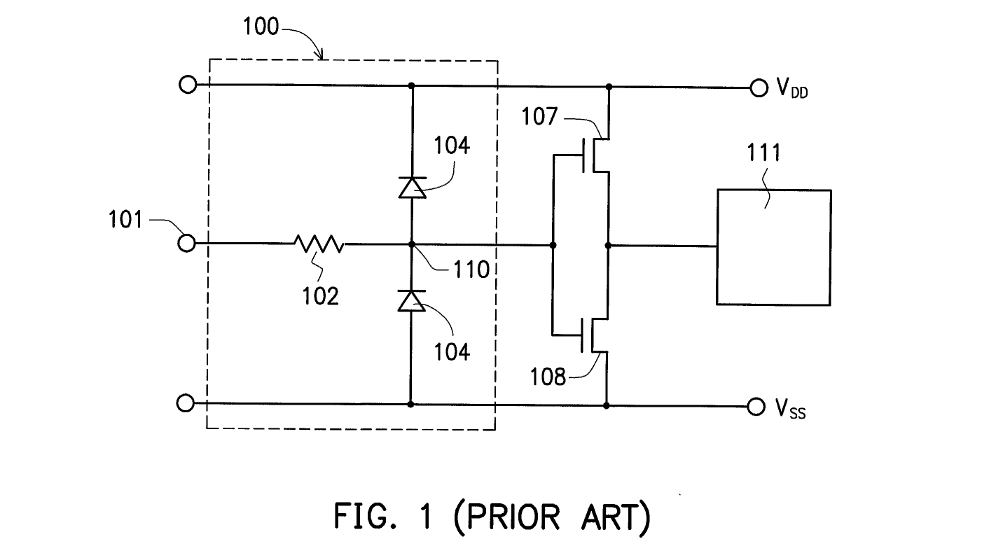

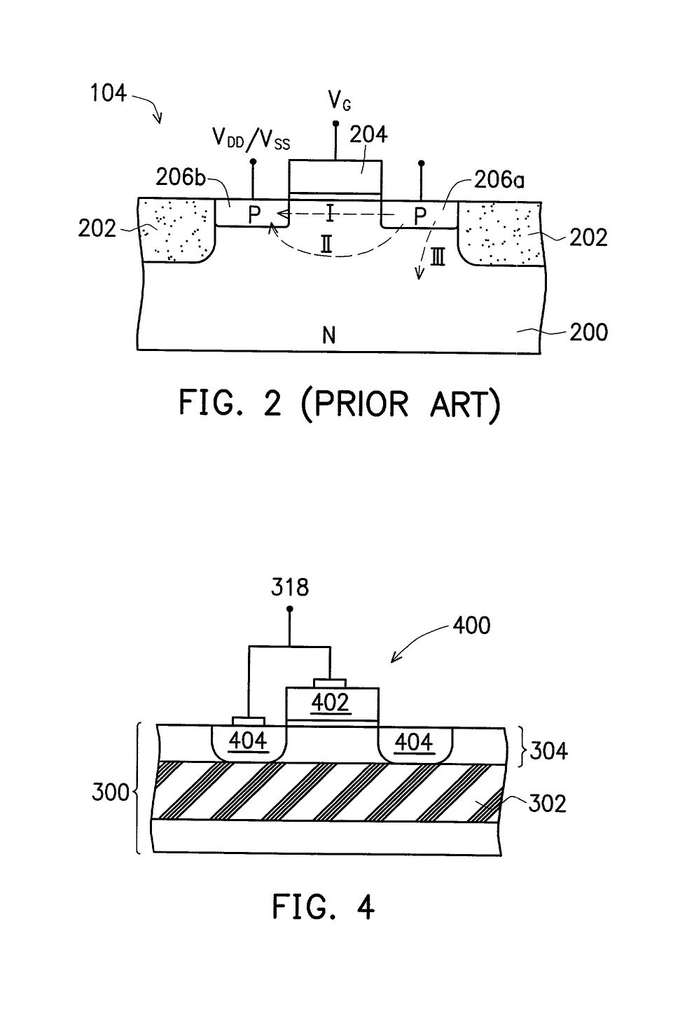

### DESCRIPTION OF THE PREFERRED EMBODIMENTS

A device fabricated on a silicon on insulator (SOI) has advantages of low power consumption, low threshold operation and high performance and therefore, many semiconductor devices have been developed to be formed on SOI. This invention integrates the ESD protection structure on SOI and with the structure of the internal circuits so as to reduce the cost of the product. This invention further forms an input resistor in a single crystal Si layer on an insulating material layer so as to obtain an ESD protection with higher resistance. Additionally, a sided P/N junction is formed in the single crystal Si layer to prevent a vertical junction.

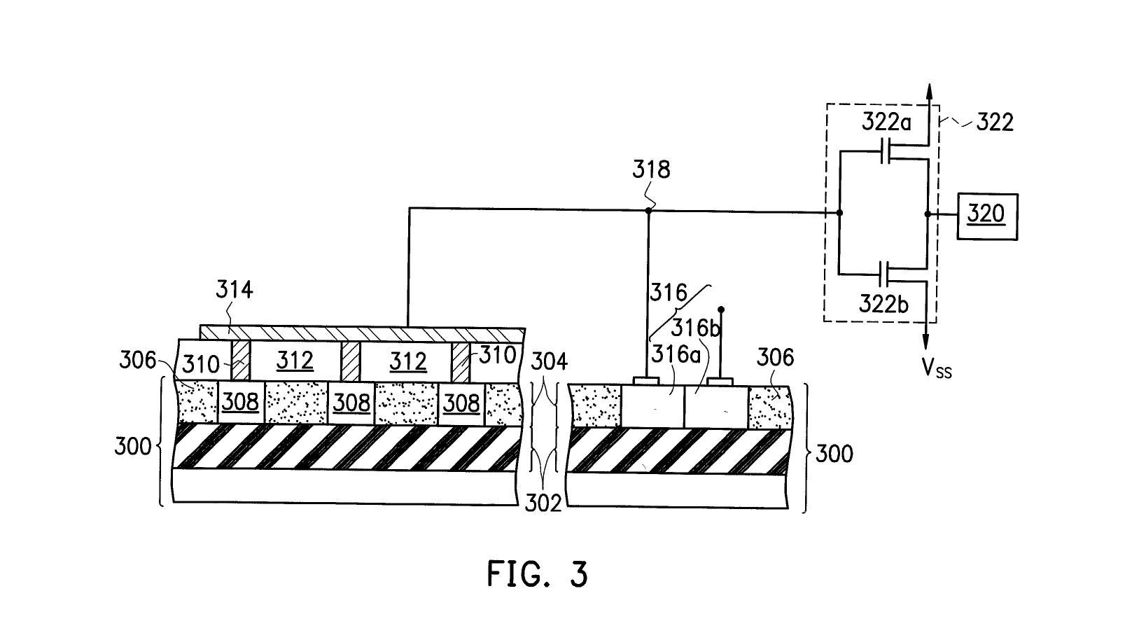

FIG. 3 illustrates a semiconductor structure of an ESD protection having a single crystal Si-sided junction diode according to the preferred embodiment of the invention. A buried insulating material layer 302 such as silicon oxide layer is formed in a semiconductor substrate 300 by separation by implanted oxygen (SIMOX), for example. Therefore, the buried insulating material layer 302 has a single Si layer 304 with a thickness of about 1000 angstroms thereon, which the single Si layer 304 serves as a single crystal substrate for the subsequent semiconductor process.

As shown in FIG. 4, an isolation structure 306 such as shallow trench isolation is formed in the single silicon layer 304 to define active areas. The isolation structure 306 defines the single silicon crystal layer into one or more single crystal lines to serve as an input resistor. The single crystal line 308 with lower dosage and used as a resistor has higher resistance. In addition, the width of the single crystal line 308 decides the resistance of the input resistor; that is, the narrower the width of the single crystal is, the higher resistance the input resistor has.

On the other hand, the isolation structure 306 defines a single crystal Si-sided junction region 316 which includes a first doped region 316a and a second doped region 316b. The first doped region 316a and the second doped region 316b are adjacent to each other, wherein the first doped region 316a is doped with P-type dopants and the second doped region 316b is doped with N-type dopants, for example. When the first doped region 316a is an N-type doped region, the second doped region 316b is a P-type doped region. Accordingly, the first doped region 316a and the second doped region 316b together compose a P/N junction to serve as a single crystal Si-sided junction diode. Since the buried insulating material layer 302 blocks underneath the first doped region 316a and the second doped region 316b, the single crystal Si junction region 316 only has a lateral P/N shallow junction of about 1000 angstroms deep, so that an undesired situation such as a vertical junction or a parasitic junction can be avoided.

Thereafter, the single crystal Si lines 308 are connected to plugs 310, which are isolated by insulating material 312, and each plug 310 connects to a metal layer 314.

The metal layer 314 and the first doped region 316a are electrically connected to a node 318 by conductive layers (not shown), and the node 318 is coupled to the internal circuit 320 by a conductive layer (not shown). A P-type FET 322a and a P-type FET 322b serving as an input buffer can be disposed between the internal circuit 320 and the node 318. The second doped region 316b of the single crystal Si-sided junction region 316b is electrically connected to the terminals of each corresponding power supply such as V_{SS} or V_{DD}.

Moreover, the single crystal Si-sided junction diode can be a MOS transistor 400 as illustrated in FIG. 4. The MOS transistor 400 including al gate 402 and a source/drain region 404 is fabricated in the single crystal Si layer 306 above the buried insulating material layer 302 as well, wherein the gate 402 and one of the source/drain region 404 electrically connects to the node 318 by wiring lines. A P/N junction is formed due to opposite conductivity of the dopants in the source/drain region 404 and the single crystal Si layer 304. Since the insulating material layer 302 is formed under the source/drain region 404, the lateral junction is formed as the structure shown in FIG. 3. Therefore, the MOS transistor can be used as a single crystal Si-sided junction diode.

Further, the single crystal Si-sided junction diode can be the combination of two or more diodes. One terminal of each diode connects to the node 318, and the other terminal of each diode electrically connects to the terminal of each corresponding power supply.

Therefore, this invention fabricates an ESD protection structure over a semiconductor substrate 300 having an insulating material layer 302 thereon. The ESD protection structure is disposed between an input pad (not shown) and an integrated circuit of the internal circuit 320, as shown in FIG. 3. The ESD protection includes at least a single crystal Si resistor 308 and at least a single crystal Si-sided junction diode 316, which both are formed on the insulating material layer 302. The metal layer 314 is formed above the insulating material layer 302 to electrically connect the single crystal Si resistor 308, the single crystal Si-sided junction diode 316 and the internal circuit 320.

Since the ESD protection circuit in this invention is formed on SOI, the ESD structure can be integrated with the internal circuit formed on the SOI, on the same semiconductor substrate. Accordingly, the device formed on the SOI has high performance, the ESD can protect the internal circuit from being damaged, and the fabricating cost is reduced.

In addition, the input resistor of ESD protection circuit is formed by a single crystal Si, so that high resistance of ESD can be easily obtained.

The formation of a sided junction diode of ESD protection circuit on the SOI can prevent vertical junction.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A ESD protection structure having a single crystal Si-sided diode used to protect an internal circuit, the ESD protection structure electrically connected between an input pad and a node and the internal circuit electrically connected to the node, the ESD protection structure comprising:
a single crystal Si resistor formed over an insulating material layer, electrically coupled between the input pad and the node; and
at least a single crystal silicon-sided junction diode formed over the insulating material layer, wherein each of the diodes is electrically coupled between one terminal of a corresponding power supply and a node.

2. The structure according to claim 1, wherein the insulating material layer is made of oxide.

3. The structure according to claim 1, wherein the insulating material layer includes a SOI.

4. The structure according to claim 1, further comprising an input buffer electrically coupled between the node and the internal circuit.

5. The structure according to claim 1, wherein the single crystal resistor is made of a single silicon layer on the insulating material layer.

6. The structure according to claim 1, wherein the single crystal Si-sided junction diode includes a P/N junction formed on the insulating material layer.

7. The structure according to claim 1, wherein the single crystal Si-sided junction diode includes a MOS transistor formed over the insulating material layer, and one of the source/drain region of the MOS electrically connects to a gate by a wiring line.

8. The structure according to claim 1, wherein the single crystal Si-sided junction diodes comprises:
a first diode, electrically connected between the node and one terminal of a first power supply; and
a second diode, electrically connected between the node and one terminal of a second power supply.

9. A ESD protection structure having a single crystal Si-sided diode used to protect an internal circuit formed from an insulating material layer on a SOI, the ESD protection structure electrically connected between an input pad and a node and the internal circuit electrically connected to the node, the ESD protection structure comprising:
an input resistor including a plurality of single resistors formed over the insulating material layer, wherein each of the single resistors is electrically coupled between the input pad and the node; and
at least a single crystal sided junction diode formed over the insulating material layer, wherein each of the diodes is electrically coupled between one terminal of a corresponding power supply and a node.

10. The structure according to claim 9, further comprising an input buffer electrically coupled between the node and the internal circuit.

11. The structure according to claim 9, wherein the single crystal resistor is made from a single silicon layer on the insulating material layer.

12. The structure according to claim 9, wherein the single crystal Si-sided junction diode includes a P/N junction formed on the insulating material layer.

13. The structure according to claim 9, wherein the single crystal Si-sided junction diode includes a MOS transistor formed over the insulating material layer, and one of the source/drain region of the MOS electrically connects to a gate by a wiring line.

14. A semiconductor structure of ESD protection, the ESD protection electrically connects between an input pad and an integrated circuit, the semiconductor structure comprising:
a semiconductor substrate;
an insulating layer, formed on the semiconductor substrate;
at least a single crystal Si resistor, folded over the insulating layer;
at least a single crystal Si-sided junction diode, formed over the insulating layer;
a first conductive layer, formed over the insulating layer, used to electrically connect one terminal of the single crystal Si resistor and the input;
a second conductive layer, formed over the insulating layer, used to electrically connect another terminal of the single crystal Si resistor and the integrated circuit; and
a third conductive layer, formed over the insulating layer, used to connect the single crystal Si-sided junction diode and the integrated circuit.

15. The structure according to claim 14, wherein the single crystal Si resistor includes a single crystal silicon layer.

16. The structure according to claim 14, wherein the single crystal sided junction diode includes a single crystal silicon P/N junction.

17. The structure according to claim 14, wherein the single crystal Si-sided junction diode includes a MOS transistor, and one source/drain region of the MOS electrically connects to a gate by a wiring line.

18. The structure according to claim 14, wherein at least a single crystal Si resistor includes a plurality of single crystal Si resistors.

19. The structure according to claim 18, wherein the single crystal Si resistors are isolated by an isolation structure.

20. The structure according to claim 19, wherein the isolation structure includes a shallow trench isolation.
